(19) United States
(12) Patent Application Publication
(10) Pub. No.: US 2023/0006424 A1
(43) Pub. Date: Jan. 5, 2023

(54) BURIED HETEROSTRUCTURE SEMICONDUCTOR OPTICAL AMPLIFIER AND METHOD FOR FABRICATING THE SAME

(71) Applicant: NATIONAL RESEARCH COUNCIL OF CANADA, Ottawa (CA)

(72) Inventor: Omid SALEHZADEH EINABAD, Orleans (CA)

(21) Appl. No.: 17/757,189

(22) PCT Filed: Dec. 11, 2020
(86) PCT No.: PCT/CA2020/051707

§ 371 Date: Jun. 10, 2022

Related U.S. Application Data
(60) Provisional application No. 62/946,633, filed on Dec. 11, 2019.

(51) Int. Cl. H01S 5/227; H01S 5/343; H01S 5/22; H01S 5/30

(52) U.S. Cl. CPC H01S 5/227; H01S 5/34313; H01S 5/2222; H01S 5/3054; H01S 2304/04

(57) ABSTRACT

A method for fabricating a buried heterostructure semiconductor optical amplifier is provided. The method includes a step providing a patterned dielectric layer on a substrate, the patterned dielectric layer having openings to expose uncovered regions of the substrate. The method also includes, in a single metal organic chemical vapour deposition (MOCVD) run: etching the uncovered regions of the substrate to form angles at corresponding edges thereof and diffusing a p-dopant in the substrate to obtain a p-dopant distribution in a portion of the substrate; etching a portion of the p-dopant thereby defining a recess in the substrate and growing a n-blocking layer in the recess; sequentially growing, over a portion of the n-blocking layer, an active region, a p-overclad, a p-contact, and a p-metal contact; and growing a n-metal contact on a backside of the substrate. The single MOCVD run combines selective area growth, p-dopant diffusion and etching techniques.

### TECHNICAL FIELD

The technical field generally relates to photonic devices and related systems, as well as methods for manufacturing the same. More particularly, the technical field relates to buried heterostructure semiconductor optical amplifiers and related systems, and methods for fabricating the same.

### BACKGROUND

An optical amplifier is a device that receives an input signal and generates an output signal having a higher power than the input signal.

Existing types of optical amplifiers include but are not limited to erbium-doped fiber amplifier (EDFA), Raman amplifier (ROA) and semiconductor optical amplifier (SOA). These optical amplifiers are all associated with respective challenges. For example, the EDFA is not only expensive to manufacture, but it is also bulky, because it requires a pump source, a coupler and an isolator. The ROA is associated with similar challenges but is even more expensive to produce than the EDFA. The SOA is typically more compact than the EDFA and ROA, can be more easily monolithically integrated with other devices and is also generally cheaper to produce. However, the noise figure is generally better in EDFA and ROA than in SOA.

Buried heterostructure SOA (BHet SOA) is a subclass of optical amplifiers. The fabrication of a BHet SOA has been commonly carried out along the <011> direction of the substrate (sometimes referred to as the “conventional direction”). One method for manufacturing a BHet SOA relies on three epitaxial growth steps, such as metalorganic chemical vapour deposition (MOCVD) growth steps, resulting in a complex and lengthy process.

There is thus a need for techniques, methods, systems and devices that addresses or mitigate at least some of the challenges presented above.

### SUMMARY

In accordance with one aspect, there is provided a method for fabricating a buried heterostructure semiconductor optical amplifier, comprising:
coating a substrate with a dielectric layer;
defining openings in the dielectric layer to obtain uncovered regions of the substrate;
etching, in situ, the uncovered regions of the substrate to form angles at corresponding edges thereof;
diffusing, in situ, a p-dopant in the substrate to obtain a p-dopant distribution in a portion of the substrate, the p-dopant distribution having a distribution profile being provided by the angles formed at the corresponding edges of the uncovered regions of the substrate;
etching, in situ, a portion of the p-dopant, thereby defining a tapered recess in the substrate;
growing a n-blocking layer in the tapered recess;
sequentially growing an active region over a portion of the n-blocking layer, a p-overclad over the active region, a p-contact over the p-overclad and a p-metal contact over the p-contact; and
growing a n-metal contact on a backside of the substrate to obtain the buried heterostructure semiconductor optical amplifier.

In some embodiments, the dielectric layer is a silicon oxide.

In some embodiments, the substrate is an n-type substrate.

In some embodiments, the n-type substrate is InP.

In some embodiments, the method further comprises cleaning the substrate before coating the substrate with the dielectric layer.

In some embodiments, said defining the openings in the dielectric layer comprises defining narrow openings in the dielectric layer and defining large openings.

In some embodiments, each narrow opening has a width ranging from about 2 μm to about 5 μm and each large opening has a width ranging from about 50 μm to about 250 μm.

In some embodiments, the dielectric layer has a thickness ranging from about 1000 Å to about 15000 Å.

In some embodiments, defining the openings in the dielectric layer comprises orienting the openings with an angle ranging from about 0° to about 10° with a <0-11> direction of the substrate.

In some embodiments, the angle is about 0°.

In some embodiments, the angle is about 7°.

In some embodiments, said etching, in situ, the uncovered regions of the substrate is carried out using a shallow etch.

In some embodiments, said shallow etch comprises etching the substrate for 1000 Å to about 15000 Å.

In some embodiments, said etching, in situ, the uncovered regions of the substrate comprises using a precursor selected from methyl iodide, carbon tetrabromide, carbon chloride tetrabromide, carbon bromide trichloride and carbon tetrachloride.

In some embodiments, said diffusing, in situ, the portion of the p-dopant in the substrate includes diffusing Zn.

In some embodiments, the distribution profile has a vertical diffusion depth ranging from about 0.4 μm to about 1.0 μm.

In some embodiments, said diffusing, in situ, the portion of the p-dopant in the substrate is carried out using a ratio of lateral diffusion rate to vertical diffusion rate in the range of about 0.5 to about 1.0.

In some embodiments, the tapered recess has a vertical dimension ranging from about 0.7 μm to about 1.7 μm.

In some embodiments, said growing the n-blocking layer in the tapered recess comprises growing an InP blocking layer.

In some embodiments, the n-blocking layer has a thickness ranging from about 0.5 μm to about 0.8 μm.

In some embodiments, said growing the active region comprises growing at least one quantum well.

In some embodiments, said growing the active region comprises growing a bulk material.

In some embodiments, said growing the active region comprises growing quantum dots.

In some embodiments, said growing the p-overclad over the active region comprises growing an InGaAs layer.

In some embodiments, the method further comprises doping the InGaAs with Zn.

In some embodiments, the method further comprises thinning the backside of the substrate before growing the n-metal contact thereon.

In accordance with another aspect, there is provided a method for fabricating a buried heterostructure semiconductor optical amplifier, comprising:
providing a patterned dielectric layer on a substrate, the patterned dielectric layer having openings to expose uncovered regions of the substrate;
in a single metal organic chemical vapour deposition (MOCVD) run:
   etching the uncovered regions of the substrate to form angles at corresponding edges thereof and diffusing a p-dopant in the substrate to obtain a p-dopant distribution in a portion of the substrate;
   etching a portion of the p-dopant thereby defining a recess in the substrate and growing a n-blocking layer in the recess;
   sequentially growing, over a portion of the n-blocking layer, an active region, a p-overclad, a p-contact, and a p-metal contact; and
   growing a n-metal contact on a backside of the substrate,
wherein said single MOCVD run combining selective area growth, p-dopant diffusion and etching techniques.

In accordance with another aspect, there is provided a buried heterostructure semiconductor optical amplifier, comprising:
a substrate having a <0-11> direction;
an active region having a longitudinal axis, the longitudinal axis being oriented with an angle ranging from about 0° to about 10° with respect to the <0-11> direction of the substrate; and
lateral npnp blocking layers for confining the current in the active region.

In some implementations, there is provided a method combining selective area growth (SAG), in situ Zn-diffusion using MOCVD techniques and in situ etching techniques in a single MOCVD run to obtain a BHet SOA structure having a lateral npnp blocking layer.

In some implementations, there is provided a method for fabricating a BHet SOA oriented along an angle ranging from about 0° to about 10° with a <0-11> direction of the substrate. In some embodiments, the BHet SOA is monolithically integrated with an optical modulator. In some embodiments, the angle is about 7°.

Other features will be better understood upon reading of embodiments thereof with reference to the appended drawings.

### BRIEF DESCRIPTION OF THE DRAWINGS

FIG. 1 is an example of a shallow ridge SOA from prior art.

FIG. 2 is an example of a BHet SOA from prior art.

FIG. 3 illustrates an embodiment of a BHet SOA.

FIGS. 4A-H show the steps of a method for fabricating a BHet SOA, in accordance with one embodiment.

FIG. 5 illustrates a layout of a dielectric mask used to fabricate a BHet SOA, in accordance with one embodiment.

FIGS. 6A-D are scanning electron microscopy (SEM) images of different embodiments of BHet SOAs.

FIGS. 7A-B are SEM images of different embodiments of BHet SOAs.

FIGS. 8A-C are SEM images of a BHet SOA, in accordance with one embodiment.

FIGS. 9A-B are SEM images of a BHet SOA, in accordance with one embodiment.

FIGS. 10A-B illustrate angles formed at edges of openings of the dielectric layer.

### DETAILED DESCRIPTION

In the following description, similar features in the drawings have been given similar reference numerals. In order to not unduly encumber the figures, some elements may not be indicated on some figures if they were already mentioned in preceding figures. It should also be understood herein that the elements of the drawings are not necessarily drawn to scale and that the emphasis is instead being placed upon clearly illustrating the elements and structures of the present embodiments.

The terms “a”, “an” and “one” are defined herein to mean “at least one”, that is, these terms do not exclude a plural number of elements, unless stated otherwise. It should also be noted that terms such as “substantially”, “generally” and “about”, that modify a value, condition or characteristic of a feature of an exemplary embodiment, should be understood to mean that the value, condition or characteristic is defined within tolerances that are acceptable for the proper operation of this exemplary embodiment for its intended application.

In the present description, the terms “connected”, “coupled”, and variants and derivatives thereof, refer to any connection or coupling, either direct or indirect, between two or more elements. The connection or coupling between the elements may be mechanical, physical, optical, acoustical, operational, electrical, wireless, or a combination thereof.

In the present description, the terms “light” and “optical”, and any variants and derivatives thereof, are intended to refer to electromagnetic radiation in any appropriate region of the electromagnetic spectrum and are not limited to visible light. For example, in one embodiment, the terms “light” and “optical” may encompass electromagnetic radiation in one or more regions of the electromagnetic spectrum, such as, for example and without being limitative, the millimeter, terahertz, visible and ultraviolet regions.

It will be appreciated that positional descriptors indicating the position or orientation of one element with respect to another element are used herein for ease and clarity of description and should, unless otherwise indicated, be taken in the context of the figures and should not be considered limiting. It will be understood that spatially relative terms (e.g., “away”, “vertical” and “horizontal”, “top” and “bottom”, “over”, “under”, “front” and “rear”, “behind”, “side” and the like) are intended to encompass different positions and orientations in use or operation of the present embodiments, in addition to the positions and orientations exemplified in the figures.

In the following description, the expression “quantum well” or “QW” generally refers to a heterostructure in which charged carriers of at least one type (i.e., electrons and/or holes) are confined in one direction (typically out-of-plane) and free in the other two directions (typically the in-plane directions). Quantum confinement is a quantum property that emerges when a particle is localized in a volume that has at least one reduced lateral dimension, e.g., a few nanometers. In this situation, the energy of the particle becomes quantized in this direction.

The expression “device” refers to a component or an assembly associated with a functionality. For example, an “photonic device” is a device that can accomplish a specific functionality involving the use or manipulation photons and/or charges carriers.

Techniques and methods for fabricating a BHet SOA using an integrated process are provided. Various embodiments of these techniques and methods will be described in greater detail after the following overview of some theoretical considerations.

General Theoretical Background

The fabrication of a BHet SOA oriented along the direction of <0-11> of the substrate may be desirable in cases where a monolithic integration of SOA with another optoelectronic component such as an optical modulator is sought.

However, methods for fabricating such a BHet SOA remain challenging, as it will be outlined below.

The fabrication of a BHet SOA along <0-11> direction may be achieved using a method relying on three epitaxial steps, such as MOCVD growth steps. In this method, a base epitaxial growth including a n-InP layer and an active region layer is carried out on an n-InP substrate. After forming a narrow mesa via an ex-situ etching, a blocking layer is grown via a SAG process. Then, a blanket p-type overclad is grown. Finally, a mesa is formed via an ex-situ etching, followed by a metallization step. In this method, the current confinement is achieved via npnp blocking layers that are formed as a result of the process. This method, relying on three MOCVD growth steps is complex and lengthy. In addition, the relatively poor quality of the npnp blocking layer overgrown along the <0-11> has hindered the success of this method.

An alternative method would be to employ a SAG technique to reduce the number of epitaxial steps during the fabrication of the SOA. An example of this approach is disclosed in U.S. Pat. No. 5,659,565. The teachings of this document relate to the fabrication of SOAs along the <011> direction, i.e., along the conventional direction, but being tilted by about 5° thereof. In this method, the active core is located adjacent to a thin SiOₓ dielectric mask and is surrounded by a p-type InP overclad. According to this method, the leakage of the current into the substrate is suppressed by the SiOₓ, dielectric mask. The method reported in this document is compatible with SOAs fabricated along the <011> direction only.

Buried Heterostructure Semiconductor Optical Amplifier

Techniques and methods to produce a BHet SOA are provided. In accordance with one broad aspect, there is provided a method that combines SAG, in situ MOCVD p-dopant, such as Zn, diffusion and in situ etching techniques in a single MOCVD run to manufacture a BHet SOA structure having lateral npnp blocking layers, as it will be described in greater detail below. In nearly all variants, the BHet SOA are based on III-V semiconductors.

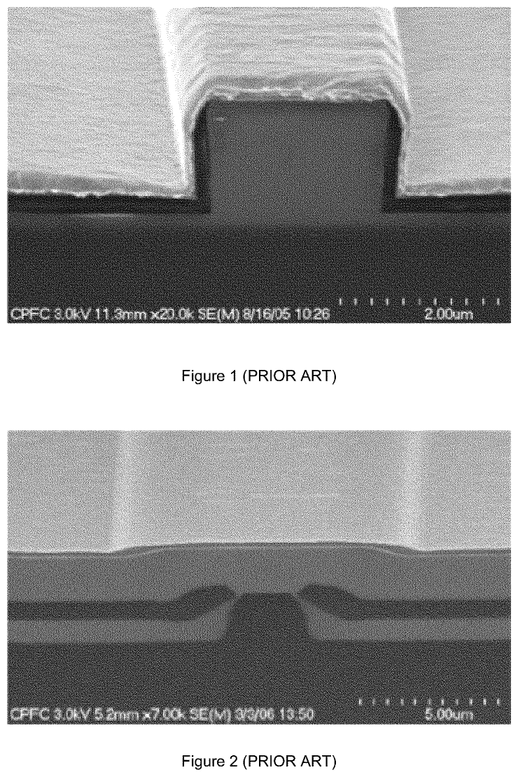

The embodiments of the methods for fabricating a BHet SOA that will now be presented can be carried in a single continuous process, i.e., an in-situ process or integrated process, which can be, for example and without being limitative a single MOCVD process. The complexity associated with these embodiments is relatively low and comparable to the complexity of designing shallow ridge SOA. An example of a shallow ridge SOA from prior art is illustrated in FIG. 1 (PRIOR ART). However, the resulting devices are relatively more reliable than the shallow ridge SOA. An example of a BHet SOA from prior art is illustrated in FIG. 2 (PRIOR ART).

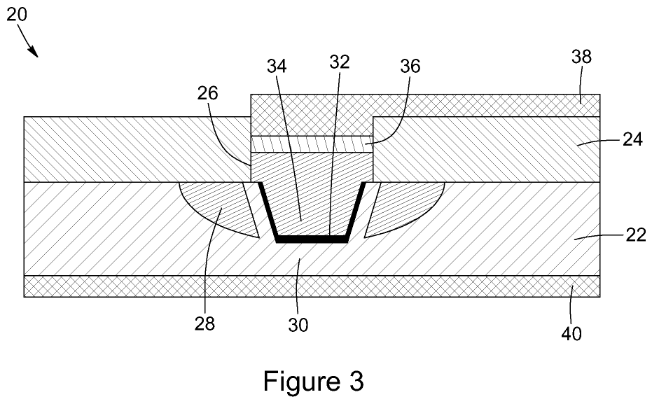

An exemplary embodiment of a BHet SOA 20 is shown in FIG. 3. As illustrated, the BHet SOA 20 includes a substrate 22. In some embodiments, the substrate is an n-type substrate. A dielectric layer 24, which can be for example and without limitative an oxide layer, is provided on top of the substrate 22. The dielectric layer 24 includes an opening 26 defined therein. The BHet SOA 20 also includes a p-dopant distribution 28 in a portion of the substrate 22. In some embodiments, the p-dopant is Zn. As illustrated, the BHet SOA 20 includes an n-blocking layer 30 that is provided in a region under the opening 26 and, in some embodiments, under a portion of the dielectric layer 24. An active region 32 is provided on at least a portion of the n-blocking layer 30. A p-overclad 34 is in contact with the active region 32 and a p-contact 36 is provided on top of the overclad 34. In the illustrated embodiment, the p-overclad 34 extends over the active region 32. The BHet SOA 20 also includes a p-metal contact 38 extending over the p-contact 36 and a n-metal contact 40 provided on a backside of the BHet SOA 20.

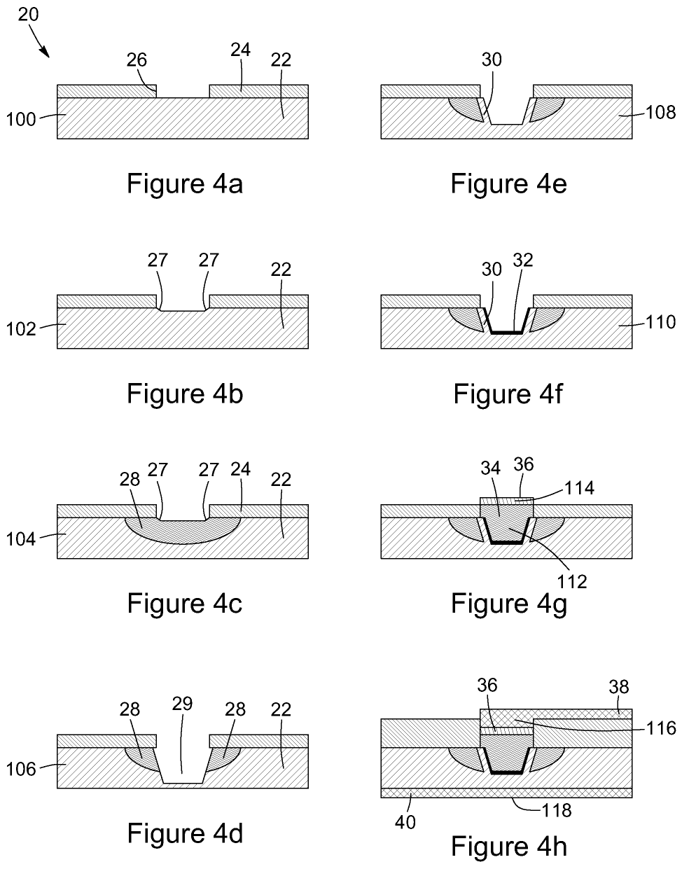

Referring to FIGS. 4A-H, an embodiment of a method for fabricating the BHet SOA 20 is illustrated.

The method includes a step of coating the substrate 22 with a dielectric layer 24. A non-limitative example of the dielectric layer 24 is a silicon oxide (SiOₓ). The dielectric layer 24 can be provided on the substrate 22 using coating and deposition techniques that are already known in the art. The substrate 22 is an n-type substrate, such as, for example and without being limitative, InP. It is to be noted that, in some embodiments, the method includes one or more precleaning steps before coating the substrate 22. Such precleaning steps can be useful to remove contaminants from the external surface of the substrate 22.

The step of coating the substrate 22 is followed by a step 100 of defining openings 26 in the dielectric layer 24 to obtain uncovered regions of the substrate. Coating the substrate 22 with the dielectric layer 24 and defining the openings 26 therein to obtain the uncovered regions of the substrate 22 are made using common microfabrication techniques. For example, and without being limitative, the step 100 of defining the openings 26 in the dielectric layer 24 may include patterning a photoresist layer provided on top of the dielectric layer 24 and etching the same after its patterning. The dielectric layer 24 can be coated with a photoresist layer of positive photoresist or negative photoresist. A characteristic of the positive photoresist is that the portion of the positive photoresist that is exposed to light (e.g., through a photomask during an “exposition step”) becomes soluble to a photoresist developer (i.e., during a “developing step”). Upon exposition to light through the photomask, the photo-sensitive material forming the positive photoresist will be degraded by light and the photoresist developer will dissolve the portions exposed to light, whereas the blocked or unexposed portions of the photoresist remain insoluble to the photoresist developer. After exposition and development of the positive photoresist, the patterns provided therein are thus a copy of the mask. A characteristic of the negative photoresist is that the portion of the negative photoresist that is exposed to light (i.e., through the photomask during the “exposition step”) becomes insoluble to the photoresist developer (i.e., during the “developing step”). Upon exposition to light through the photomask, the photo-sensitive material forming the negative photoresist will be cross-linked or polymerized by light and the photoresist developer will dissolve the blocked portions or portions unexposed to light, whereas the exposed portions of the photoresist remain insoluble to the photoresist developer. After exposition and development of the negative photoresist, the patterns provided therein are thus complementary to the mask. The photoresist, positive or negative, can be spin-coated on the dielectric layer core or could alternatively be coated or deposited with other deposition techniques. In a typically spin-coating step, a few milliliters of the photoresist are placed, poured or dispensed on the dielectric layer. A rotational movement is then imparted to the substrate 22 having the dielectric layer 24 thereon and a rotational speed equal to or greater than 1000 rpm can be reached. The centrifugal force due to the rotation of the substrate 22 spreads the dispensed photoresist into a thin film of substantially uniform thickness and the excess is spun off the edge of the substrate 22 and dielectric layer 24. Part of the solvent contained in the photoresist can evaporate from the photoresist layer during the rotation of the substrate. The photoresist layer is then exposed to electromagnetic radiation through openings provided in a photomask placed above the photoresist layer. Of note, electron beam lithography could alternatively be used. As in most microfabrication process, the electromagnetic radiation is in the UV range. In some embodiments, exposing the photoresist layer to electromagnetic radiation comprises illuminating the photoresist layer with a beam having at least one ultraviolet spectral line. In some embodiments, the spectral line comprises 436 nm, 405 nm and 365 nm. After the exposition of the photoresist layer, the photoresist layer is developed in an appropriate solvent. In some embodiments, remaining portions of the photoresist layer after the development can be thermally treated in order to harden the same. In some embodiments, the remaining portions can be hardened using deep ultra-violet (DUV) radiation. Once the development of the photoresist is complete, a step of etching the exposed portions of the dielectric layer, which is followed by a step of stripping off the remaining portions of the photoresist layer, thus resulting in the dielectric layer having openings defined therein and portions of the substrate being uncovered, namely the uncovered regions. An example of the dielectric layer 24 coating the substrate 22 is illustrated in FIG. 4A.

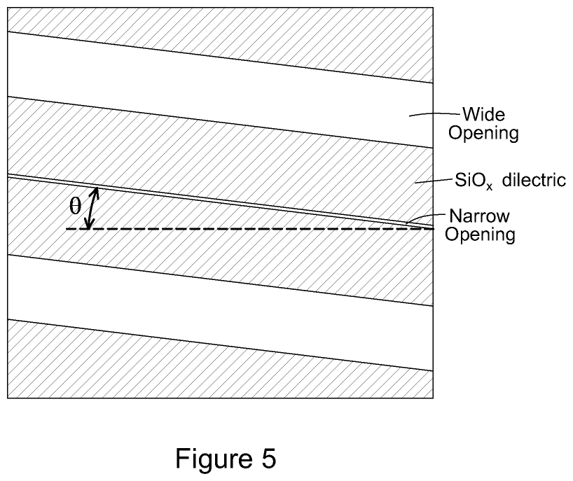

In some embodiments, the thickness of the dielectric layer 24, which corresponds to the depth of the openings 26 provided therein, is in the range of about 1000 Å to about 15000 Å. As for the width (i.e., an opening size), it is typically in the range of about 2 μm to about 5 μm. Such openings 26 are referred to as “narrow openings”. It is to be noted that the dielectric layer 24 can also be provided with large openings to control the global growth rate during the SAG step(s). An example of the layout of the dielectric mask is illustrated in FIG. 5.

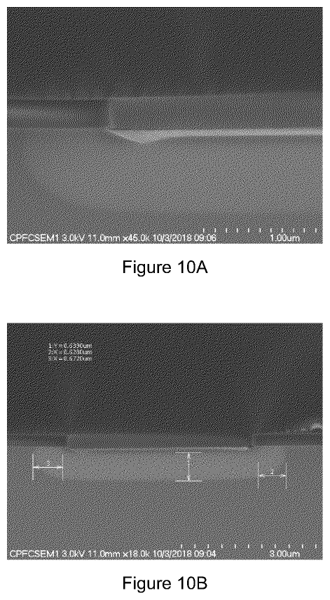

Once the openings 26 are defined in the dielectric layer 24, a step 102 of etching, in situ, the uncovered regions of the substrate 22 to form angles 27 at corresponding edges thereof is carried out FIGS. 10A-B illustrate the angles 27 formed at the edges of the openings 26.

The angles 27 are different than the relatively flat surface of the uncovered regions of the substrate 22. For example, and without being limitative, the angles 27 can supplementary, i.e., their sum can be 180°. In the context of the current description, the angles 27 are measured in a direction aligned with the width of the openings 26 (i.e., perpendicular to their longitudinal axis). This step 102 could be referred as a “shallow etch step”, as the depth of this etching is relatively small. Indeed, the aim of this in situ etching is to form the angles 27 at the edges of the openings 26 of the dielectric layer 24, rather than etching the substrate 22. In some embodiments, the depth of the shallow in situ etching is in the range of about 0.1 μm to about 0.5 μm. Non-limitative examples of precursors that can be used for this step 102 are methyl iodide, carbon tetrabromide, carbon chloride tetrabromide, carbon bromide trichloride, carbon tetrachloride and other precursors that are compatible with MOCVD technologies. An example of the result of this step 102 is illustrated in FIG. 4B.

With reference to FIG. 5, It is to be noted that the longitudinal axis of the openings 26, i.e., the one running perpendicular to both the width and the depth of the same, is generally aligned along the <0-11> direction of the substrate or forms an angle θ ranging from about 0° to about 10° relative to the <0-11> direction. In some embodiments, the angle is about 0°. In other embodiments, the angle is about 7°. The angle of about 7° can be useful to minimize back-reflections from the facets.

The step 102 of forming the angles 27 at the edges of the openings 26 is followed by a step 104 of diffusing, in situ, a p-dopant in the uncovered regions of the substrate to obtain a p-dopant distribution 28 in a portion of the substrate 22. This step 104 is illustrated in FIG. 4C. In some embodiments, the p-dopant is Zn. The portion of the substrate 22 is generally aligned with the uncovered regions of the substrate 22, but also extends, in some implementations, under at least a portion of the dielectric layer 24. The p-dopant distribution 28 has a distribution profile that is provided by the angles 27 formed at the corresponding edges of the uncovered regions of the substrate 22 being aligned with the openings 26. The p-dopant distribution 28 could either be isotropic or anisotropic. In the first case, the ratio of lateral to vertical diffusion rate is approximately the same, whereas, in the second case, the ratio of lateral to vertical diffusion rate is relatively different. In some embodiments, the diffusion depth (i.e., vertical direction) is in the range of about 0.4 μm to about 1.0 μm. In some embodiments, the ratio of lateral to vertical diffusion rate is in the range of about 0.5 to about 1.0. It is to be noted that the ratio of lateral to vertical rate depends at least on the diffusion conditions and the shallow etching depth carried out in the prior step 102. For instance, the presence of the angles 27 at the edges of the openings 26 generally increases the lateral diffusion rate of the p-dopant (with respect to the vertical diffusion rate).

Now referring to FIG. 4D, the method also includes a step 106 of etching, in situ, a portion of the p-dopant, thereby defining a tapered recess 29 in the substrate. In some embodiments, the depth (i.e., vertical dimension) of this in situ etching is in the range of about 0.7 μm to about 1.7 μm. Unetched portion(s) of the p-dopant can be seen in FIG. 4D. As illustrated, the dimensions of the tapered recess 29 can be different (e.g., smaller) that the distribution profile of the p-dopant. In the illustrated embodiment, the distribution profile of the p-dopant has a semi-circular or semi-elliptical cross-section and the tapered recess 29 has a truncated v-shaped cross-section. The result of the etching of the truncated v-shaped cross-section in the semi-elliptical cross-section of the distribution profile of the p-dopant is two p-dopant regions each having a cross-section having a shape resembling a fin, the two p-dopant regions being located on a respective side of the tapered recess 29.

The method then includes subsequent growth steps 108 to 114, as illustrated in the non-limitative embodiment of FIGS. 4E-H. An n-blocking layer 30 is grown in the tapered recess 29 in step 108. A non-imitative example of an n-blocking layer 30 is an n-InP layer. In some embodiments, the thickness of the n-blocking layer 30 is in the range of about 0.5 μm to about 0.8 μm. While various n-doping levels can be achieved, the n-doping level of the n-blocking layer 30 typically ranges from about 6e17 cm⁻³ to about 2e18 cm⁻³. The method also includes a step 110 of growing an active region 32 over at least a portion of the n-blocking layer 30. It is to be noted that the active region 32 is electronically and/or optically active and could be made from a broad variety of architectures, designs, structures and/or materials. For example, and without being limitative, the active region 32 could be in the form of a bulk material, multi-quantum wells, quantum dots or a combination thereof. The refractive index of the active region 32 is larger and, in some implementations, much larger than the refractive index of its surrounding, thus enabling the required optical confinement for the device to operate. A p-overclad 34 is then grown over the active region 32 in step 112. The p-overclad 34 is epitaxially grown. A non-limitative of the material forming the p-overclad 34 is InGaAs. The p-doping of can be achieved, for example and without being limitative, using Zn or any other appropriate dopants. While various doping levels could be used, the p-doping level of the p-overclad 34 is in the range of about 5e17 cm⁻³ to about 2e18 cm⁻³. The method then includes a step 114 of a growing a p-contact 36 above the p-overclad 34. The p-contact 26 can be, for example and without being limitative, made from InGaAs. The doping level of the p-contact layer 36 is in the range of about 1e19 cm⁻³ to about 2e19 cm⁻³. A p-metal contact 38 is then grown over the p-contact 36 in step 116, and an n-metal contact 40 is grown on a backside of the substrate to obtain the buried heterostructure semiconductor optical amplifier in step 118.

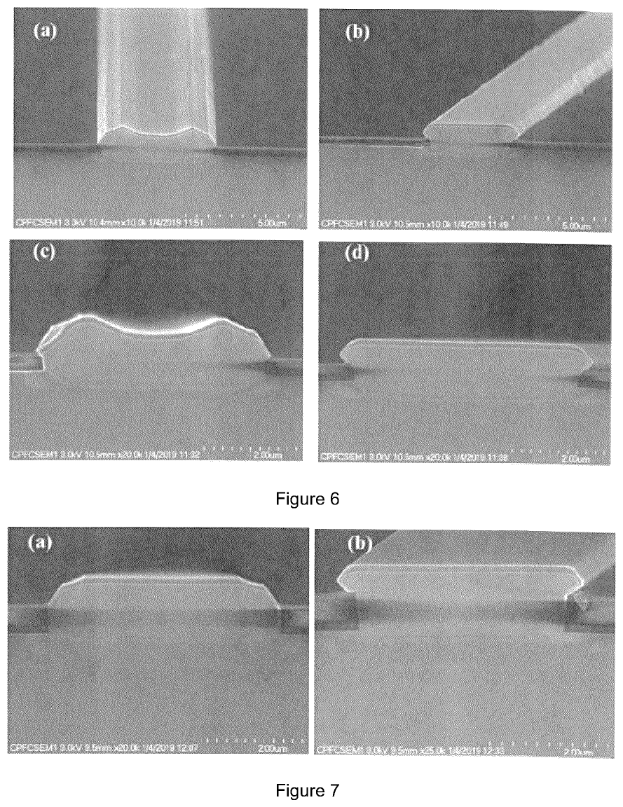

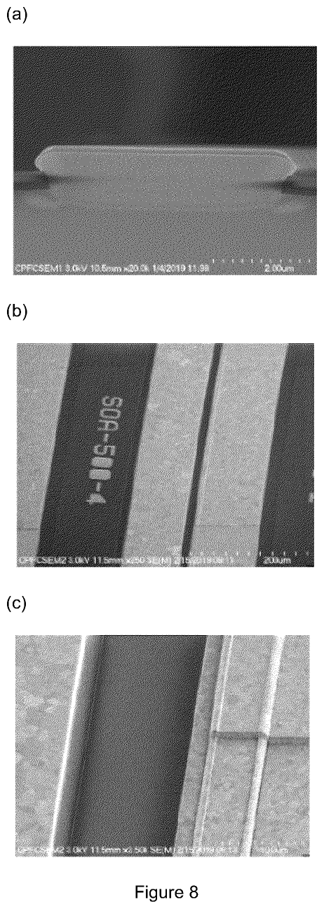

A schematic representation of the obtained device is illustrated in FIGS. 3 and 4H, and images of structures fabricated according to the present method are shown in FIGS. 6 to 8. The achieved lateral npnp configuration is useful to laterally confine the current, and thus for avoiding or at least minimizing the leakage thereof. The double blocking layer, i.e., the two npnp junctions defined by the substrate 22, the p-dopant distribution 28, the n-blocking layer 30 and the p-overclad 30 do not only confine the current in the active region 32, but also confines the current down of the valley (i.e., the bottom region of the active region 32). As such, a semiconductor-based blocking layer can be implemented in BHet SOA devices to effectively minimize lateral current leakage. It is to be noted that the device can be obtained in a single MOCVD run by employing a combination of SAG and in situ etching and growth.

One advantage associated with the embodiments of the method described herein is that they result in devices having lateral current blocking layers, which is at least partially due to the methods relying on SAG, p-dopant (e.g., Zn) diffusion and in situ etching step(s) in a single MOCVD run.

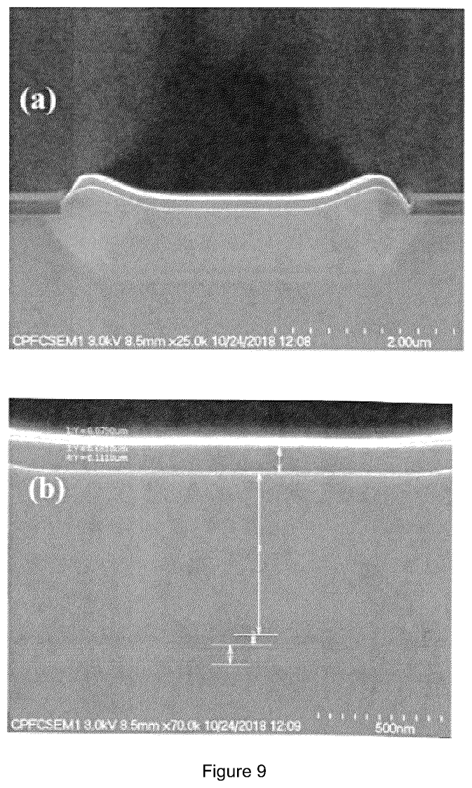

In other embodiments, the methods provided herein can be adapted so that the active region or core is not buried into the substrate, but is rather above the substrate, i.e., protruding therefrom. In such embodiments, the active region is surrounded by the p-overclad material. An example of a device resulting from this process is illustrated in FIG. 9. In this embodiment, the method includes all the steps illustrated in FIGS. 4A-H, except for the steps illustrated in FIGS. 4B-D.

Example of an Implementation

Now that several embodiments of techniques for fabricating BHet SOA have been presented, a nonlimitative exemplary implementation will now be presented.

An n-substrate, for example and without being limitative, an InP substrate or any other III-V substrate is covered with a dielectric layer such as SiOₓ. The thickness of SiOₓ is in the range of about 1000 Å to about 15000 Å. The substrate is then patterned to open two sets of windows. The first set of windows includes narrow openings, for the growth of the device structure, and has a width (i.e., an opening size) in the range of about 2 μm to about 5 μm. The second set of windows includes wide windows, for adjusting the overall growth rate, and has a width (i.e., an opening size) in the range of about 50 μm to about 250 μm. The separation between narrow and wide openings was in the range of about 25 μm to about 250 μm. The stripes were oriented with an angle θ in the range of about 0° to about 10° relative to the <0-11> direction.

The substrate is then loaded into a semiconductor growth tool, such as an MOCVD reactor after a preclean process. Prior to the Zn diffusion process, a shallow in situ etching is carried out using ethyl iodide. Alternatively, methyl iodide, carbon tetrabromide, carbon tetrachloride or carbon bromide trichloride could be used for the in situ etching step. The depth of the shallow in situ etching is in the range of about 0.1 μm to about 0.5 μm. The step of shallow etching is required to control the ratio of the lateral to vertical Zn diffusion rate of the subsequent step that will now be described.

The step of Zn diffusion is then carried out. The Zn diffusion depth is in the range of about 0.4 μm to about 1.0 μm. The ratio of lateral to vertical diffusion rate is in the range of about 0.5 to about 1.0, depending on the diffusion conditions and the shallow etching depth carried out in the prior step.

After the step of Zn diffusion, a step of in situ etching is carried out. The depth of the in situ etching is in the range of about 0.7 μm to about 1.7 μm.

After the step of in situ etching, an n-blocking layer, such as n-InP layer, with thickness in the range of about 0.5 μm to about 0.8 μm and n-doping level in the range of about 6e17 cm⁻³ to about 2e18 cm⁻³ is grown.

After this step of growing the n-blocking layer, an active region is grown. The active region could be in the form of a bulk material, multi-quantum wells or quantum dots.

As a final epitaxial step, a p-overclad layer, such as a p-InP layer, and a p-contact, such as InGaAs layer, are grown. The p-doping is achieved using Zn or any other appropriate dopants. The doping level of the overclad is in the range of about 5e17 cm⁻³ to about 2e18 cm⁻³, and the doping level of the contact layer is in the range of about 1e19 cm⁻³ to about 2e19 cm⁻³.

In order to complete the fabrication process, after depositing a dielectric layer and providing opening via over the contact layer in the device region, a p-metal contact is deposited on the contact layer. Finally, after thinning the wafer, an n-metal contact is deposited on the backside of the wafer.

In another implementation, there is provided an SOA structure wherein the active core is not buried into the substrate but is above the substrate and is surrounded by a p-overclad. An example of such a fabricated SOA structure is shown FIG. 9. In this process some of steps which have been described above are omitted. For example, the steps of step of shallow etching, Zn diffusion and in situ etching, illustrated in FIGS. 4A-H can be omitted to obtain such devices.

Several alternative embodiments and examples have been described and illustrated herein. The embodiments described above are intended to be exemplary only. A person skilled in the art would appreciate the features of the individual embodiments, and the possible combinations and variations of the components. A person skilled in the art would further appreciate that any of the embodiments could be provided in any combination with the other embodiments disclosed herein. The present examples and embodiments, therefore, are to be considered in all respects as illustrative and not restrictive. Accordingly, while specific embodiments have been illustrated and described, numerous modifications come to mind without significantly departing from the scope defined in the appended claims.

1. A method for fabricating a buried heterostructure semiconductor optical amplifier, comprising:
coating a substrate with a dielectric layer;
defining openings in the dielectric layer to obtain uncovered regions of the substrate;
etching, in situ, the uncovered regions of the substrate to form angles at corresponding edges thereof;
diffusing, in situ, a p-dopant in the substrate to obtain a p-dopant distribution in a portion of the substrate, the p-dopant distribution having a distribution profile being provided by the angles formed at the corresponding edges of the uncovered regions of the substrate;
etching, in situ, a portion of the p-dopant, thereby defining a tapered recess in the substrate;
growing a n-blocking layer in the tapered recess;
sequentially growing an active region over a portion of the n-blocking layer, a p-overclad over the active region, a p-contact over the p-overclad and a p-metal contact over the p-contact; and
growing a n-metal contact on a backside of the substrate to obtain the buried heterostructure semiconductor optical amplifier.

2. The method of claim 1, wherein the dielectric layer is a silicon oxide.

3. The method of claim 1, wherein the substrate is an n-type substrate.

4. The method of claim 3, wherein the n-type substrate is InP.

5. (canceled)

6. The method of claim 1, wherein said defining the openings in the dielectric layer comprises defining narrow openings in the dielectric layer and defining large openings.

7. The method of claim 6, wherein each narrow opening has a width ranging from about 2 μm to about 5 μm and each large opening has a width ranging from about 50 μm to about 250 μm.

8. The method of claim 1, wherein the dielectric layer has a thickness ranging from about 1000 Å to about 15000 Å.

9. The method of claim 1, wherein defining the openings in the dielectric layer comprises orienting the openings with an angle ranging from about 0° to about 10° with a <0-11> direction of the substrate.

10. The method of claim 9, wherein the angle is about 0° or about 7°.

11. (canceled)

12. The method of claim 1, wherein said etching, in situ, the uncovered regions of the substrate is carried out using a shallow etch.

13. The method of claim 12, wherein said shallow etch comprises etching the substrate for 1000 Å to about 15000 Å.

14. The method of claim 1, wherein said etching, in situ, the uncovered regions of the substrate comprises using a precursor selected from methyl iodide, carbon tetrabromide, carbon chloride tetrabromide, carbon bromide trichloride and carbon tetrachloride.

15. The method of claim 1, wherein said diffusing, in situ, the portion of the p-dopant in the substrate includes diffusing Zn.

16. The method of claim 1, wherein the distribution profile has a vertical diffusion depth ranging from about 0.4 μm to about 1.0 μm.

17. The method of claim 1, wherein said diffusing, in situ, the portion of the p-dopant in the substrate is carried out using a ratio of lateral diffusion rate to vertical diffusion rate in the range of about 0.5 to about 1.0.

18. The method of claim 1, wherein the tapered recess has a vertical dimension ranging from about 0.7 μm to about 1.7 μm.

19. The method of claim 1, wherein said growing the n-blocking layer in the tapered recess comprises growing an InP blocking layer.

20. The method of claim 1, wherein the n-blocking layer has a thickness ranging from about 0.5 μm to about 0.8 μm.

21. The method of claim 1, wherein said growing the active region comprises at least one of:
growing at least one quantum well;
growing a bulk material; or
growing quantum dots.

22. (canceled)

23. (canceled)

24. The method of claim 1, wherein said growing the p-overclad over the active region comprises growing an InGaAs layer.

25. (canceled)

26. The method of claim 1, further comprising thinning the backside of the substrate before growing the n-metal contact thereon.

27. A method for fabricating a buried heterostructure semiconductor optical amplifier, comprising:
providing a patterned dielectric layer on a substrate, the patterned dielectric layer having openings to expose uncovered regions of the substrate;
in a single metal organic chemical vapour deposition (MOCVD) run:
etching the uncovered regions of the substrate to form angles at corresponding edges thereof and diffusing a p-dopant in the substrate to obtain a p-dopant distribution in a portion of the substrate;
etching a portion of the p-dopant thereby defining a recess in the substrate and growing a n-blocking layer in the recess;
sequentially growing, over a portion of the n-blocking layer, an active region, a p-overclad, a p-contact, and a p-metal contact; and
growing a n-metal contact on a backside of the substrate,
wherein said single MOCVD run combining selective area growth, p-dopant diffusion and etching techniques.

28. A buried heterostructure semiconductor optical amplifier, comprising:
a substrate having a <0-11> direction;
an active region having a longitudinal axis, the longitudinal axis being oriented with an angle ranging from about 0° to about 10° with respect to the <0-11> direction of the substrate; and
lateral npnp blocking layers for confining the current in the active region.
